(19) United States
(12) Patent Application Publication
(10) Pub. No.: US 2025/0273927 A1
(43) Pub. Date: Aug. 28, 2025

(54) OPTICAL MODULE

(71) Applicant: HISENSE BROADBAND MULTIMEDIA TECHNOLOGIES CO., LTD., Qingdao (CN)

(72) Inventors: Jianwei MU, Qingdao (CN); Tao WU, Qingdao (CN); Shuang JIN, Qingdao (CN); Sigeng YANG, Qingdao (CN); Qian SHAO, Qingdao (CN); Huizheng BIAN, Qingdao (CN); Chengshuang LUO, Qingdao (CN); Jingqi SU, Qingdao (CN)

(73) Assignee: HISENSE BROADBAND MULTIMEDIA TECHNOLOGIES CO., LTD., Qingdao (CN)

(21) Appl. No.: 18/759,754

(22) Filed: Jun. 28, 2024

Related U.S. Application Data
(63) Continuation of application No. PCT/CN2024/084431, filed on Mar. 28, 2024.

(30) Foreign Application Priority Data
Feb. 26, 2024 (CN) 2024 1 0208556.3
Feb. 26, 2024 (CN) 2024 1 0208801.0
Feb. 26, 2024 (CN) 2024 2 0351756.X

(51) Int. Cl. H01S 5/024; H01S 5/026

(52) U.S. Cl. CPC H01S 5/02415; H01S 5/0261

(57) ABSTRACT

An optical module provided in the present disclosure includes: a circuit board provided with a through-hole; a light emission component configured for generating an optical signal; a driver located beside the light emission component and electrically connected to the light emission component; a lens component connected to the circuit board at its bottom and is covered over the light emission component, configured for changing a transmission direction of the optical signal generated by the light emission component; a support component, which has a top located inside the through-hole and is connected to the circuit board; a temperature regulating mechanism located below the lens assembly and connected to the support component at its bottom; wherein the temperature regulating mechanism is located below or beside the light emission component, configured for regulating an operating temperature of the light emission component.

### CROSS-REFERENCE TO RELATED APPLICATIONS

This application is a continuation of the application filed on Mar. 28, 2024, with the application number PCT/CN2024/084431, which claims the priority to the application No. 202410208556.3 filed with the China National Intellectual Property Administration on Feb. 26, 2024, the priority to the application No. 202410208801.0 filed with the China National Intellectual Property Administration on Feb. 26, 2024, and the priority to the application No. 202420351756.X filed with the China National Intellectual Property Administration on Feb. 26, 2024, which are incorporated herein by references in their entirety.

### FIELD OF THE INVENTION

The present disclosure relates to the field of optical communication technologies, and in particular to an optical module.

### BACKGROUND OF THE INVENTION

With the development of cloud computing, mobile Internet, video, artificial intelligence and other new services and application models, the development and progress of optical communication technology has become increasingly important. In optical communication technology, the optical module is a tool for achieving mutual conversion of optical and electric signals, is one of the key devices in optical communication equipment, and is at a core position in optical communication.

### SUMMARY OF THE INVENTION

One aspect of the present disclosure provides an optical module, including a circuit board, a light emission component, a lens component, a support component, and a temperature regulating mechanism. The circuit board is provided with a through-hole. The light emission component is electrically connected to the circuit board, for generating an optical signal. The driver is electrically connected to the circuit board and is located beside the light emission component, and the driver is electrically connected to the light emission component. The lens component is connected to the circuit board at its bottom and is covered over the light emission component, configured for changing a transmission direction of the optical signal generated by the light emission component. The top of the support component is located inside the through-hole, and the support component connects with the circuit board. The thermal conductivity coefficient of the support component is greater than or equal to that of the circuit board. The temperature regulating mechanism is located below the lens component and its bottom is connected to the support component. The temperature regulating mechanism is located below or beside the light emission component, configured for regulating the operating temperature of the light emission component.

Another aspect of the present disclosure provides an optical module, including: a circuit board, which is provided with a through-hole; a lens component, the bottom of which is connected to the circuit board, configured for changing the transmission direction of an optical signal; an optical chip, which is located below the lens component, and includes at least one of a light emission component and a light reception component; a support component, which is connected to the circuit board, with its top located inside the through-hole; wherein the support component supports and connects with the optical chip, and the thermal conductivity coefficient of the support component is greater than that of the circuit board.

Yet another aspect of the present disclosure provides an optical module, including: a circuit board, which is provided with a through-hole; a lens component, the bottom of which is connected to the circuit board, configured for changing a transmission direction of an optical signal; an optical chip, which is located below the lens component, and includes at least one of a light emission component and a light reception component; a matching chip, which is located below the lens component and beside the optical chip and correspondingly connected to the optical chip by wire bonding, and includes at least one of a driver and a TIA; a support component, which is connected to the circuit board, and the top of the support component is located inside the through-hole; wherein the support component supports and connects with the optical chip and the matching chip, and the thermal conductivity coefficient of the support component is greater than that of the circuit board.

### BRIEF DESCRIPTION OF THE DRAWINGS

To more clearly describe the technical solutions of the present disclosure, the accompanying drawings to be used in the embodiments will be described briefly below. Apparently, the accompanying drawings as described below are only those of some embodiments of the present disclosure, and for those skilled in the art, other accompanying drawings may also be derived from these accompanying drawings. In addition, the accompanying drawings as described below can be regarded as schematic diagrams and are not intended to limit the actual size of the product, the actual process of the method, or the actual timing of the signal involved in the disclosed embodiments.

FIG. 1 is a partial architecture view of an optical communication system provided according to some embodiments of the present disclosure;

FIG. 2 is a partial structure view of a master computer provided according to some embodiments of the present disclosure;

FIG. 3 is a structure view of an optical module provided according to some embodiments of the present disclosure;

FIG. 4 is an exploded view of an optical module provided according to some embodiments of the present disclosure;

FIG. 5 is an exploded diagram of an internal structure of the optical module provided according to some embodiments of the present disclosure;

FIG. 6 is a partially enlarged view of portion A in FIG. 5;

FIG. 7 is a structural diagram of a first heater provided according to some embodiments of the present disclosure;

FIG. 8 is a usage state view of a support component provided according to some embodiments of the present disclosure;

FIG. 9 is an assembly diagram I of a support component provided according to some embodiments of the present disclosure;

FIG. 10 is an assembly diagram II of a support component provided according to some embodiments of the present disclosure;

FIG. 11 is an internal structure diagram of another optical module provided according to some embodiments of the present disclosure;

FIG. 12 is an exploded diagram of the internal structure of another optical module provided according to some embodiments of the present disclosure;

FIG. 13 is a partially enlarged diagram of portion B in FIG. 12;

FIG. 14 is a structural diagram of a circuit board provided according to some embodiments of the present disclosure;

FIG. 15 is a structural diagram of another support component provided according to some embodiments of the present disclosure;

FIG. 16 is a usage state view of another support component provided according to some embodiments of the present disclosure;

FIG. 17 is a partial assembly diagram I of another support component provided according to some embodiments of the present disclosure;

FIG. 18 is a partial assembly diagram II of another support component provided according to some embodiments of the present disclosure;

FIG. 19 is a section view of another optical module provided according to some embodiments of the present disclosure;

FIG. 20 is an exploded diagram I of the internal structure of another optical module provided according to some embodiments of the present disclosure;

FIG. 21 is an exploded diagram II of the internal structure of another optical module provided according to some embodiments of the present disclosure;

FIG. 22 is a structural diagram I of another support component provided according to some embodiments of the present disclosure;

FIG. 23 is a partially enlarged view of another support component provided according to some embodiments of the present disclosure;

FIG. 24 is a structural diagram II of another support component provided according to some embodiments of the present disclosure;

FIG. 25 is a usage state view of another support component provided according to some embodiments of the present disclosure;

FIG. 26 is an internal structure diagram of yet another optical module provided according to some embodiments of the present disclosure;

FIG. 27 is an exploded diagram I of the internal structure of yet another optical module provided according to some embodiments of the present disclosure;

FIG. 28 is a partial diagram of the internal structure of yet another optical module provided according to some embodiments of the present disclosure;

FIG. 29 is an exploded diagram II of the internal structure of yet another optical module provided according to some embodiments of the present disclosure;

FIG. 30 is a structural diagram I of yet another support component provided according to some embodiments of the present disclosure;

FIG. 31 is a structural diagram II of yet another support component provided according to some embodiments of the present disclosure;

FIG. 32 is a structural diagram III of yet another support component provided according to some embodiments of the present disclosure;

FIG. 33 is a usage state view of yet another support component provided according to some embodiments of the present disclosure;

FIG. 34 is a partially enlarged view of the usage state of yet another support component provided according to some embodiments of the present disclosure;

FIG. 35 is an assembly section view I of yet another support component and a circuit board provided according to some embodiments of the present disclosure;

FIG. 36 is an assembly section view II of yet another support component and a circuit board provided according to some embodiments of the present disclosure;

FIG. 37 is a partial diagram of another lower shell part provided according to some embodiments of the present disclosure.

### DETAILED DESCRIPTION OF THE EMBODIMENTS

Some embodiments of the present disclosure will be described clearly and in detail with reference to the accompanying drawings below. Obviously, these embodiments as described are merely some, but not all, of the embodiments of the present disclosure. All other embodiments obtained by those skilled in the art based on the embodiments of the present disclosure shall be included in the protection scope of the present disclosure.

In optical communication technology, in order to establish information transmission between information processing devices, it is necessary to load information onto light and thus achieve transmission of the information by use of propagation of light. Herein, the light loaded with information is an optical signal. The optical signal propagated in the information transmission devices can reduce loss of optical power, and thus achieve high-speed, long-distance, and low-cost information transmission. The information that can be recognized and processed by the information processing device is an electrical signal. Optical network units (ONU), gateways, routers, switches, mobile phones, computers, servers, tablets, and televisions are common information processing devices, while optical fibers and waveguides are common information transmission devices.

Conversion of the optical signals and the electrical signals between the information processing device and the information transmission device can be achieved by use of the optical module. For example, at least one of optical signal input terminal and optical signal output terminal of the optical module connects with an optical fiber, and at least one of electrical signal input terminal and electrical signal output terminal of the optical module connects with an optical network unit. A first optical signal from the optical fiber is transmitted to the optical module, which converts the first optical signal into a first electrical signal, and then transmits the first electrical signal to the optical network unit. A second electrical signal from the optical network unit is transmitted to the optical module, which converts the second electrical signal into a second optical signal, and then transmits the second optical signal into the optical fiber. Since the information transmission among information processing devices can be performed via electrical signals, at least one of the information processing devices needs to be directly connected to the optical module, and it is unnecessary for all of the information processing devices to be directly connected to the optical module. Herein, the information processing device directly connected to the optical module is called as a master computer of the optical module. In addition, the optical signal input terminal or the optical signal output terminal of the optical module can be referred to as “optical port”, and the electrical signal input terminal or the electrical signal output terminal of the optical module can be referred to as “electrical port”.

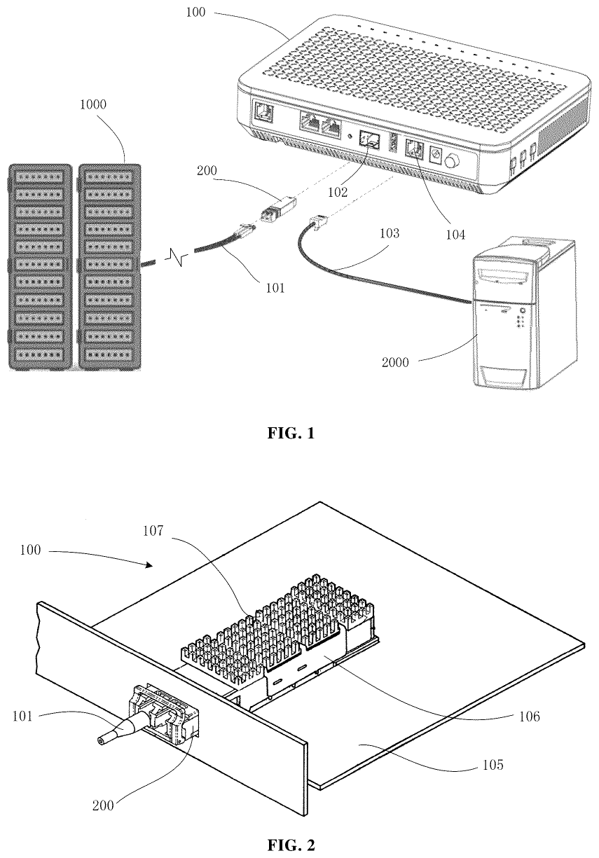

FIG. 1 is a partial architecture view of an optical communication system provided according to some embodiments of the present disclosure. As shown in FIG. 1, the optical communication system mainly includes a remote information processing device 1000, a local information processing device 2000, a master computer 100, an optical module 200, an optical fiber 101, and a network cable 103.

One end of the optical fiber 101 extends towards the remote information processing device 1000, and the other end of the optical fiber 101 is coupled to the optical module 200 via an optical port of the optical module 200. The optical signal can undergo a total reflection in the optical fiber 101, and propagation of the optical signal in a total reflection direction can almost maintain an original optical power. The optical signal undergoes multiple total reflections in the optical fiber 101, such that the optical signal from the remote information processing device 1000 is transmitted into the optical module 200, or the optical signal from the optical module 200 is transmitted to the remote information processing device 1000, thereby achieving long-distance and low-power-loss information transmission.

There may be one optical fiber 101 or a plurality of optical fibers 101. The optical fiber 101 can be connected to the optical module 200 in a pluggable manner or a fixed connection manner. The master computer 100 is configured to provide data signals to the optical module 200 or receive data signals from the optical module, or to monitor or control working status of the optical module 200.

The master computer 100 includes a generally cuboid housing, and an optical module interface 102 provided on the housing. The optical module interface 102 is configured to be coupled to the optical module 200, thereby establishing a unidirectional or bidirectional electrical signal connection between the master computer 100 and the optical module 200.

The master computer 100 has an external electrical interface, which can be coupled to the electrical signal network. For example, the external electrical interface includes a Universal Serial Bus (USB) or a network cable interface 104. The network cable interface 104 is configured to be coupled with the network cable 103, thereby establishing a unidirectional or bidirectional electrical signal connection between the master computer 100 and the network cable 103. One end of the network cable 103 is connected to the local information processing device 2000, and the other end of the network cable 103 is connected to the master computer 100, so as to establish an electrical signal connection between the local information processing device 2000 and the master computer 100. For example, a third electrical signal emitted by the local information processing device 2000 is transmitted to the master computer 100 through the network cable 103. The master computer 100 generates a second electrical signal based on the third electrical signal, and the second electrical signal from the master computer 100 is transmitted to the optical module 200. The optical module 200 converts the second electrical signal into a second optical signal, and transmits the second optical signal to the optical fiber 101. The second optical signal is transmitted to the remote information processing device 1000 through the optical fiber 101. For example, a first optical signal from the remote information processing device 1000 propagates through the optical fiber 101. The first optical signal from the optical fiber 101 is transmitted to the optical module 200. The optical module 200 converts the first optical signal into the first electrical signal, and transmits the first electrical signal to the master computer 100. The master computer 100 generates a fourth electrical signal based on the first electrical signal, and transmits the fourth electrical signal into the local information processing device 2000. It should be noted that the optical module is a tool for achieving the conversion between optical and electrical signals, and during the conversion between optical and electrical signals as described above, no change is made to the information, but methods for encoding and decoding the information can be changed.

In addition to the Optical Network Unit, the master computer may include Optical Line Terminal (OLT), Optical Network Terminal (ONT), Data Center Server and so on.

FIG. 2 is a partial structure view of a master computer provided according to some embodiments of the present disclosure. In order to clearly illustrate the connection relationship between the optical module 200 and the master computer 100, FIG. 2 only shows the structure of the master computer 100 related to the optical module 200. As shown in FIG. 2, the master computer 100 further includes a PCB circuit board 105 disposed within a housing, a cage 106 disposed on a surface of the PCB circuit board 105, a radiator 107 disposed on the cage 106, and an electrical connector disposed inside the cage 106. The electrical connector is configured to be coupled to the electrical port of the optical module 200, and the radiator 107 has a raised structure, such as a fin, that increases heat dissipation area.

The optical module 200 is inserted into the cage 106 of the master computer 100 and is secured by the cage 106. Heat generated by the optical module 200 is conducted to the cage 106, and then dissipated via the radiator 107. After the optical module 200 is inserted into the cage 106, the electrical port of the optical module 200 is connected to the electrical connector provided inside the cage 106, thereby establishing a bidirectional electrical signal connection between the optical module 200 and the master computer 100. Also, the optical port of the optical module 200 is coupled with the optical fiber 101, thereby establishing a bidirectional optical signal connection between the optical module 200 and the master computer 100.

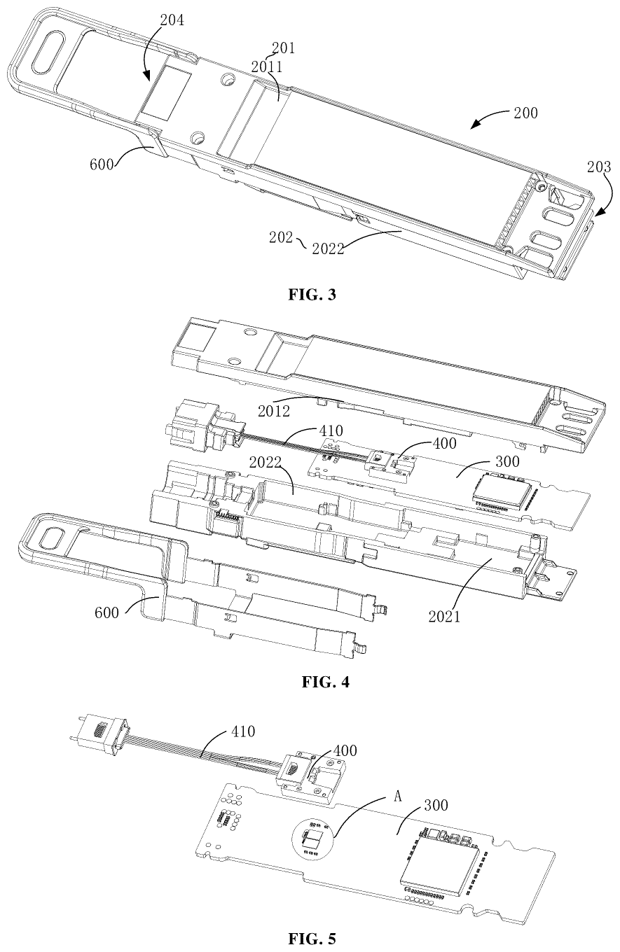

FIG. 3 is a structure view of an optical module provided according to some embodiments of the present disclosure, and FIG. 4 is an exploded view of an optical module provided according to some embodiments of the present disclosure. As shown in FIGS. 3 and 4, the optical module 200 includes a shell, and a circuit board 300 and a lens component 400 provided within the shell.

The shell may include an upper shell part 201 and a lower shell part 202. The upper shell part 201 is covered on the lower shell part 202 to form the aforementioned shell having two openings 203 and 204. The outer contour of the shell is generally in a cuboid shape.

In some embodiments, the lower shell part 202 includes a bottom plate 2021 and two lower side plates 2022 located on opposite sides of the bottom plate 2021 and disposed perpendicular to the bottom plate 2021, and the upper shell part 201 includes a cover plate 2011. The cover plate 2011 is covered on the two lower side plates 2022 of the low shell part 202 so as to form the above-mentioned shell.

In some embodiments, the lower shell part 202 includes a bottom plate 2021 and two lower side plates located on opposite sides of the bottom plate 2021 and disposed perpendicular to the bottom plate 2021, and the upper shell part 201 includes a cover plate 2011 and two upper side plates 2012 located on opposite sides of the cover plate 2011 and disposed perpendicular to the cover plate 2011, such that the two upper side plates 2012 are combines with the two lower side plates 2022 to achieve the covering of the upper shell part 201 on the lower shell part 202.

The direction along a connecting line between the two openings 203 and 204 may be consistent with the length direction of the optical module 200 or inconsistent with the length direction of the optical module 200. For example, the opening 203 is located at an end of the optical module 200 (right end in FIG. 3), and the opening 204 is also located at an end of the optical module 200 (left end in FIG. 3). Alternatively, the opening 203 is located at an end of the optical module 200, while the opening 204 is located at a side of the optical module 200. The opening 203 is an electrical port and a gold finger of the circuit board 300 extends from the electrical port and is inserted into the master computer (e.g., Optical Network Unit 100). The opening 204 is an optical port configured to be coupled by the optical fiber 101 such that the optical fiber 101 is connected with the optical module 200.

The assembling way in which the upper shell part 201 is combined with the lower shell part 202 facilitates mounting the circuit board 300, the lens component 400 and the like into the shell, such that these components may be encapsulated and protected by the upper shell part 201 and the lower shell part 202. In addition, when assembling the circuit board 300, the lens component 400 and the like, this assembling way facilitates the deployment of the positioning elements, the heat dissipation elements, and the electromagnetic shielding elements for these components, which is conducive to automated production.

In some embodiments, the upper shell part 201 and lower shell part 202 are generally made of metal materials, which facilitates achieving electromagnetic shielding and heat dissipation.

In some embodiments, the optical module 200 further includes an unlocking component 600 located outside the shell thereof. The unlocking component 600 is configured to achieve a fixed connection between the optical module 200 and the master computer or release the fixed connection between the optical module 200 and the master computer.

For example, the unlocking component 600 is located outside of the two lower side plates 2022 of the lower shell part 202, and includes a snapping part that matches with the cage 106 of the master computer 100. When the optical module 200 is inserted into the cage 106, the snapping part of the unlocking component 600 secures the optical module 200 within the cage 106. As the unlocking component 600 is pulled, the snapping part of the unlocking component 600 moves accordingly, and thus the connection relationship between the snapping part and the master computer is changed, thereby releasing the fixed connection between the optical module 200 and the master computer, such that the optical module 200 can be drawn out from the cage 106.

The circuit board 300 includes circuit wiring, electronic elements, and chips. The electronic elements and chips are connected together by the circuit wiring according to a circuit design so as to achieve various functions such as power supply, electrical signal transmission, and grounding. For example, the electronic elements may include capacitors, resistors, triodes, and Metal-Oxide-Semiconductor Field-Effect Transistors (MOSFETs). For example, the chips may include lasers, photodetectors, microcontroller units (MCUs), laser driver chips, transimpedance amplifiers (TIAs), limiting amplifiers (LAs), clock and data recovery (CDR) chips, power management chips, digital signal processing (DSP) chips and the like.

The circuit board 300 is generally a hard circuit board. Due to its relatively hard material, the hard circuit board can also achieve a load-bearing function, e.g., can stably bear the above-mentioned electronic elements and chips. The hard circuit board can also be inserted into the electrical connector in the cage 106 of the master computer 100.

The circuit board 300 further includes a gold finger formed on the surface of an end thereof, which is composed of a plurality of pins independent from each other. The circuit board 300 is inserted into the cage 106 and is conductively connected to the electrical connector disposed inside the cage 106 via the gold finger. The gold finger may be disposed only on one surface of the circuit board 300 (e.g., an upper surface shown in FIG. 4), or on both upper and lower surfaces of the circuit board 300 to provide more pins so as to be suitable to applications where a larger number of pins are required. The gold finger is configured to establish an electrical connection with the master computer to achieve power supply, grounding, Inter-Integrated Circuit (I2C) signal transmission, data signal transmission or the like. Of course, some of the optical modules can also use a flexible circuit board. The flexible circuit board is generally used in conjunction with the hard circuit board, as a supplement to the hard circuit board.

In some embodiments, a bottom of the lens component 400 is connected to the circuit board 300 and is covered over the optical chip. The optical chip includes a light emission component and/or a light reception component, etc., which are electrically connected to the circuit board 300. The lens component 400 has an optical surface such as a transmissive surface and/or a reflective surface to adjust transmission directions of optical emission and/or reception signals by a combination of the transmissive and reflective surfaces, such that the optical emission signal generated by the light emission component can be output from the optical module, and the optical signal input into the optical module can be transmitted to the light reception component. The light emission component includes a laser, and the light reception component includes a photodetector. In some embodiments, a matching chip may also be provided below the lens component 400, and the matching chip includes a driver and/or TIA, etc.

In some embodiments, the lens component 400 connects with an optical fiber strip 410, and the optical signal generated by the light emission component is transmitted to the optical fiber strip 410 via the lens component 400; alternatively, the optical signal input through the optical fiber strip 410 is transmitted to the lens component 400, and then transmitted to the light reception component via the lens component 400. Of course, in some embodiments, the lens component 400 is arranged beside the optical port of the optical module 200, and the lens component 400 directly connects with the external optical fiber.

An optical fiber connector is provided at an end of the optical fiber strip 410 for connecting the external optical fiber. In some embodiments, the optical fiber connector is laid flat in the optical port, that is, a main plane of the optical fiber connector is parallel or approximately parallel to the load-bearing plane of the optical port. Of course, in some embodiments, the optical fiber connector is laid upright in the optical port, that is, the main plane of the optical fiber connector is perpendicular or approximately perpendicular to the load-bearing plane of the optical port. FIG. 4 shows an optical fiber connector in a laid flat state.

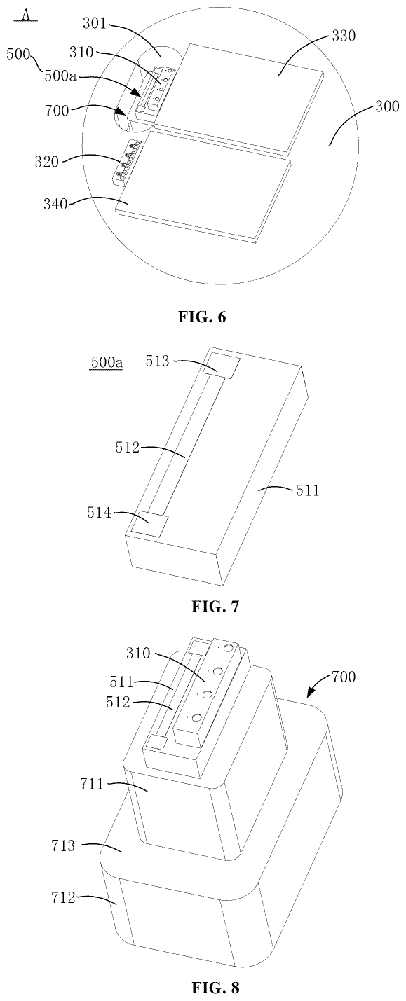

FIG. 5 is an exploded diagram of the internal structure of an optical module provided according to some embodiments of the present disclosure, and FIG. 6 is a partially enlarged view of portion A in FIG. 5. As shown in FIGS. 5 and 6, a light emission component 310 is provided below the lens component 400, and the light emission component 310 is electrically connected to the circuit board 300. The optical signal generated by the light emission component 310 is transmitted to the lens component 400, transmitted to the optical fiber strip 410 via the lens component 400, and out of the optical module through the optical fiber strip 410. In some embodiments, the light emission component 310 may be provided on the circuit board 300, such that the top surface of the light emission component 310 is higher than the top surface of the circuit board 300.

In some embodiments, a driver 330 is provided below the lens component 400 and beside the light emission component 310, and the driver 330 is electrically connected to the circuit board 300 and to the light emission component 310. The driver 330 can be provided on the circuit board 300, such that the top surface of the driver 330 is higher than the top surface of the circuit board 300. The light emission component 310 can be connected to the driver 330 by wire bonding, and the driver 330 can be connected to the circuit board 300 by wire bonding.

In some embodiments, a light reception component 320 is provided below the lens component 400. The optical signal transmitted to the lens component 400 through the optical fiber strip 410 is then transmitted to the light reception component 320 via the lens component 400. The light reception component 320 can be provided beside the light emission component 310, and the light reception component 320 can be provided on the circuit board 300, such that the top surface of the light reception component 320 is higher than the top surface of the circuit board 300.

In some embodiments, a TIA 340 is provided below the lens component 400 and beside the light reception component 320, and the TIA 340 is electrically connected to the circuit board 300 and to the light reception component 320. The TIA 340 can be provided on the circuit board 300, such that the top surface of the TIA 340 is higher than the top surface of the circuit board 300. The light reception component 320 can be connected to the TIA 340 by wire bonding, and the TIA 340 can be connected to the circuit board 300 by wire bonding.

In some embodiments, the light reception component 320 is located beside the light emission component 310. For example, the light reception component 320 and the light emission component 310 are arranged side by side in a width direction of the circuit board 300.

In some embodiments, a plurality of lasers is packaged in the light emission component 310. There may be four VCSEL lasers to be packaged in the light emission component 310, but in some embodiments of the present disclosure, the light emission component 310 is not limited to packaging four VCSEL lasers therein. In some embodiments, a transmission rate of the VCSEL lasers is 50 Gb/s, 100 Gb/s, 200 Gb/s, etc. As the transmission rate of the VCSEL laser in the light emission component 310 is higher, the high-frequency performance of the VCSEL laser is more sensitive to operating temperature of the laser. For example, the VCSEL laser can maintain its high-frequency performance only within a very small temperature range. Therefore, in order to ensure that the optical module 200 can operate in an environmental temperature range of 0° C. to 70° C., it is necessary to maintain the operating temperature of the light emission component 310 within a certain temperature range, thereby reducing the impact of the environmental temperature on its operating temperature.

In some embodiments, a plurality of photodetectors is packaged in the light reception component 320. There may be four photodetectors to be packaged in the light reception component 320, but in some embodiments of the present disclosure, the light reception component 320 is not limited to packaging four photodetectors therein.

In some embodiments, the optical module 200 includes a temperature regulating mechanism 500, which is located below the lens component 400 and is electrically connected to the circuit board 300, such that the temperature regulating mechanism 500 can generate or absorb heat to maintain the operating temperature of the light emission component 310 within a relatively constant range, thereby ensuring the high-frequency performance of the light emission component 310 by stabilizing the operating temperature of the light emission component 310 within a predetermined range. The light emission component 310 can be provided on the top of the temperature regulating mechanism 500 or beside the temperature regulating mechanism 500. The temperature regulating mechanism 500 may include a heating element, or the temperature regulating mechanism 500 may include a Therma Electric Cooler (TEC).

In some embodiments, the optical module 200 includes a support component 700, which is located below the lens component 400, and supports and connects with the light emission component 310 or the light reception component 320, etc. For example, the circuit board 300 is provided with a through-hole 301 located below the lens component 400, and the support component 700 is connected to the through-hole 301 such that a portion of the support component 700 is located inside the through-hole 301. For example, the top of the support component 700 is embedded in the through-hole 301.

In some embodiments, the thermal conductivity coefficient of the support component 700 is greater than or equal to that of the circuit board 300. The use of the support component 700 facilitates heat dissipation of optical chips and other devices, stabilizing the operating temperature of the optical chips and other devices within a predetermined range.

In some embodiments, the support component 700 may use metal or the other materials having good thermal conductivity, such as tungsten and copper. This facilitates the heat dissipation of the optical chips and other devices mounted on it, helping to maintain a relatively constant operating temperature of the optical chips and other devices on the support component 700. The shape and size of the through-hole 301 are determined with reference to the dimension of lens component 400, the available space on the circuit board 300, and the dimensions of the optical chips and other components.

In some embodiments, the support component 700 may support and connect with the light emission component 310.

In some embodiments, the support component 700 may support and connect with the temperature regulating mechanism 500. For example, the bottom of the temperature regulating mechanism 500 is connected to the top of the support component 700.

In some embodiments, as shown in FIG. 6, the light emission component 310 and the heating element 500a are arranged on the top of the support component 700, and the optical reception component 320, the driver 330, and the TIA 340 are located outside the support component 700.

In some embodiments, the support member 700 can be fixedly connected to the circuit board 300 by thermal conductive gel and the like.

In some embodiments, the support component 700 may support and connect with at least one of the optical reception component 320, the driver 330, and the TIA 340.

In some embodiments, the temperature regulating mechanism 500 includes a heating element 500a, which is located beside or below the light emission component 310. The heating element 500a is electrically connected to the circuit board 300. The heating element 500a is energized to generate heat, which can increase the temperature of the light emission component 310 and the environment temperature, thereby stabilizing the operating temperature of the light emission component 310 within a certain range, and ensuring the stability of the performance of the light emission component 310.

In some embodiments, the heating element 500a is provided below the light emission component 310, that is, the heating element 500a supports and connects with the light emission component 310.

In some embodiments, the support component 700 supports and connects with the heating element 500a. The support component 700 is configured to assist the heating element 500a in maintaining the operating temperature of the light emission component 310.

In some embodiments, the light emission component 310 is provided on the heating element 500a, the light reception component 320 is provided on the circuit board 300 and beside the light emission component 310, such that the light reception component 320 and the light emission component 310 are arranged side by side in the width direction of the circuit board 300. The TIA 340 is located beside the light reception component 320 and the driver 330, such that the TIA 340 and the driver 330 are arranged side by side in the width direction of the circuit board 300 to fully utilize the space provided below the lens component 400 and facilitate the size control of the lens component 400.

In some embodiments, there is a gap between the light reception component 320 and the heating element 500a so as to reduce the impact of heat generated by the heating element 500a on the light reception component 320.

FIG. 7 is a structural diagram of a heating element provided according to some embodiments of the present disclosure. As shown in FIG. 7, the heating element 500a includes a substrate 511 and a heating layer 512. The heating layer 512 is provided on the substrate 511, and the heating layer 512 is electrically connected to the circuit board 300 so as to be energized to generate heat. The heating layer 512 can be provided on the top surface of the substrate 511. The substrate 511 can be a ceramic substrate, but not limited to the ceramic substrate. The heating layer 512 may use resistance wires or circuit patterns formed on the substrate 511.

In some embodiments, the heating layer 512 may be provided on an edge of the top of the substrate 511. When the heating element 500a supports and connects with the light emission component 310, the heating layer 512 is located beside the light emission component 310 to ensure that the heat generated by the heating element 500a is uniformly transmitted to the light emission component 310, thereby stabilizing the operating temperature of each laser in the light emission component 310. In some embodiments, the heating layer 512 is located on an edge of the top of the substrate 511 that is away from the driver 330.

In some embodiments, the heating layer 512 extends from one end of the light emission component 310 to the other end of the light emission component 310, i.e. a length of the heating layer 512 is greater than or equal to that of the light emission component 310, such that the heat generated by the heating layer 512 can be uniformly transmitted to the light emission component 310.

In some embodiments, the heating element 500a further comprises a first pad 513 and a second pad 514, with the first pad 513 electrically connected to one end of the heating layer 512, and the second pad 514 electrically connected to the other end of the heating layer 512. The first pad 513 and the second pad 514 are used to facilitate the electrical connection of the heating layer 512 to the circuit board 300.

The first pad 513 and the second pad 514 can be provided on the top surface of the substrate 511, with the first pad 513 located at one end of the heating layer 512 and the second pad 514 located at the other end of the heating layer 512. The first pad 513 and the second pad 514 can also be provided on a side surface of the substrate 511, and the heating layer 512 extends from the top surface of the substrate 511 to the side surface of the substrate 511.

FIG. 8 is a usage state view of a support component provided according to some embodiments of the present disclosure. As shown in FIG. 8, the support component 700 includes a support portion 711 and a connection portion 712. The top of the support portion 711 is connected to the bottom of the heating element 500a, and the bottom of the support portion 711 is connected to the connection portion 712. The connection portion 712 is used to connect the circuit board 300, and the support portion 711 is configured to be embedded in the through-hole 301.

In some embodiments, the top of the support portion 711 can directly support the light emission component 310, that is, the bottom of the light emission component 310 is connected to the top of the support portion 711.

In some embodiments, the cross-sectional size of the connection portion 712 is larger than that of the supporting portion 711, such that a stepped surface 713 is formed around the bottom of the supporting portion 711. The stepped surface 713 can facilitate the connection of the support component 700 to the circuit board 300 and the adjustment of a relative height between the top of the support portion 711 and the surface of the circuit board 300. The support component 700 can be connected to the circuit board 300 by dispensing glue on the stepped surface 713. In some embodiments, the stepped surface 713 is connected to the back side of the circuit board 300.

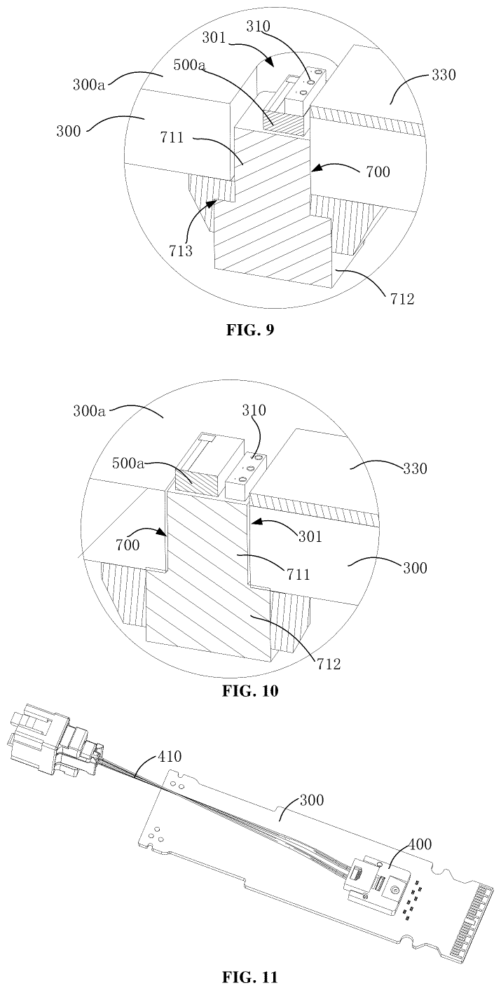

FIG. 9 is an assembly diagram I of a support component provided according to some embodiments of the present disclosure. As shown in FIG. 9, the support portion 711 of the support component 700 is located inside the through-hole 301, the top of the support portion 711 connects with the bottom of the heating element 500a, and the light emission component 310 is provided at the top of the heating element 500a. The top surface of the support portion 711 is lower than the top surface 300a of the circuit board 300, so as to control the height of the top of the light emission component 310. The connection portion 712 is located on the other side of the circuit board 300 that is away from the top surface 300a, and the connection portion 712 is connected to the circuit board 300 by the thermal conductive gel. For example, the thermal conductive gel wraps side edges of the connection portion 712 and the back side of the circuit board 300. In this way, the support component 700 can not only facilitate the installation of heating element 500a and light emission component 310, but also facilitate the connection of the circuit board 300, and also facilitate the transfer of excessive heat to the back side of the circuit board 300, thereby reducing intensive heat transfer above the top surface 300a of the circuit board 300, and thus reducing adverse effects of excessive heat on the devices provided on the top surface 300a.

In some embodiments, the height of the support portion 711 is higher than the height of the connection portion 712, such that the top of the support portion 711 is inserted into the through-hole 301 when the support component 700 is connected to the circuit board 300.

In some embodiments, the side wall of the through-hole 301 includes two circular arc faces, which are located at two ends of the side wall of the through-hole 301 to facilitate the assembly and connection between the through-hole 301 and the support component 700.

In some embodiments, the bottom of the connection portion 712 does not contact the shell of the optical module such as the lower shell part 202, so that the heat generated by the heating element 500a and directly transmitted to the shell of the optical module via the support component 700 is reduced, thereby ensuring utilization rate of the heat generated by the heating element 500a. Also, when the heating element 500a is not working, the support component 700 can facilitate the heat dissipation of the light emission component 310 to some extent, effectively avoiding an impact of a high temperature on the performance of the light emission component 310.

In some embodiments, the bottom of the connection portion 712 contacts with the lower shell part 202 to facilitate the transfer of heat generated by the light emission component 310 and the like to the lower shell part 202 via the support component 700, thereby ensuring the stability of the operating temperature of the light emission component 310.

In some existing technologies, a support block of metal or other materials is provided below the chip, mainly for heat dissipation and chip height adjustment. For example, the top of the support block supports the chip, and the bottom of the support block contacts and connects with the shell of the optical module to directly transfer the heat generated by the chip to the shell of the optical module via the support block, thereby improving efficiency of the heat dissipation of the heat generated by the chip; alternatively, the support block supports the chip such that the top surface of the chip is flush with the top surface of the circuit board, thereby facilitating the length control of the wire bonding between the chip and the circuit board.

In some embodiments, the stepped surface 713 supports and connects with the back side of the circuit board 300, thereby facilitating the connection of the connection portion 712 with the circuit board 300. For example, the thermal conductive gel connects the stepped surface 713 with the back side of the circuit board 300, and the thermal conductive gel also wraps the side edges of the connection portion 712.

FIG. 10 is an assembly diagram Il of a support component provided according to some embodiments of the present disclosure. As shown in FIG. 10, the support portion 711 is located inside the through-hole 301, and the top of the support portion 711 supports and connects with the bottom of the heating element 500a and the bottom of the light emission component 310, with the light emission component 310 located between the heating element 500a and the driver 330. The top surface of the support portion 711 is flush with the top surface 300a of the circuit board 300, so as to control a height of the top of the light emission component 310. The connection portion 712 is located on the back side of the circuit board 300, and is assembled and connected to the back side of the circuit board 300 by the stepped surface 713. In some embodiments, the connection portion 712 is connected to the back side of the circuit board 300 via the thermal conductive gel, and the thermal conductive gel wraps the side edges of the connection portion 712 and connects with the circuit board 300.

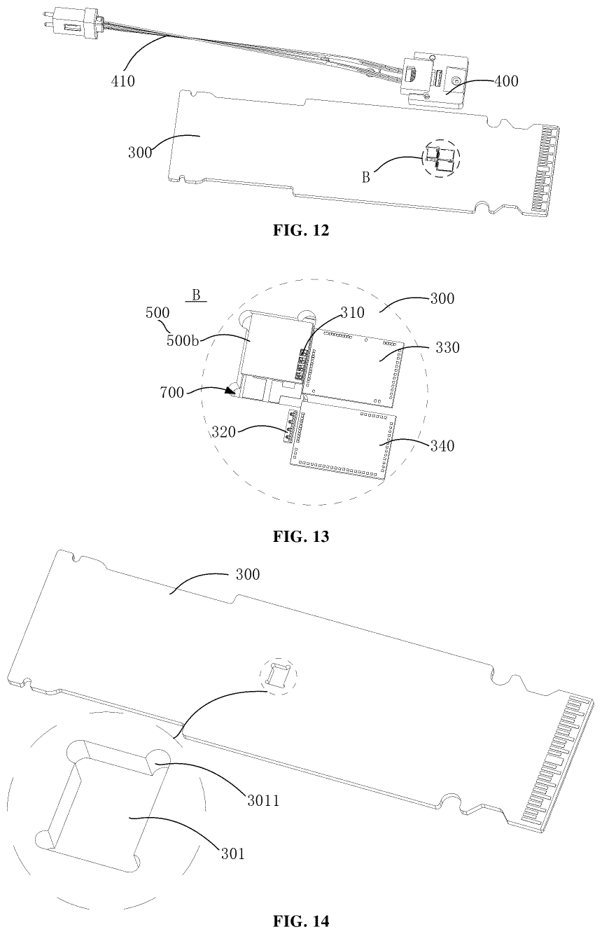

FIG. 11 is an internal structure diagram of another optical module provided according to the embodiment of the present disclosure, FIG. 12 is an exploded diagram of the internal structure of another optical module provided according to the embodiment of the present disclosure, and FIG. 13 is a partially enlarged diagram of portion B in FIG. 12, in which FIG. 11 shows a state where an optical fiber joint is vertically arranged. As shown in FIGS. 11 to 13, a TEC 500b is provided below the lens component 400, and the top of the TEC 500b supports and connects with the light emission component 310. The TEC 500b is electrically connected to the circuit board 300. The TEC 500b can be energized to release or absorb heat, thereby adjusting the temperature around the light emission component 310 to maintain the operating temperature of the light emission component 310 within a relatively stable range.

In some embodiments, a temperature detection element is provided on the TEC 500b, for detecting the temperature around the light emission component 310. The temperature detection element can sample thermistors or the like.

In some embodiments, the support component 700 supports and connects with the TEC 500b. The top of the support component 700 is connected to the bottom of the TEC 500b, and the top of the TEC 500b supports and connects with the light emission component 310. The support component 700 is connected to the circuit board 300, such that the TEC 500b is located inside the through-hole 301.

In some embodiments, the light emission component 310 is located on an edge of the top of the TEC 500b, the driver 330 is located on the circuit board 300 and beside the light emission component 310. The top surface of the TEC 500b can be lower than the top surface of the circuit board 300, or the top surface of the TEC 500b can be flush with the top surface of the circuit board 300, so as to facilitate the control of the relative height between the top surface of the light emission component 310 and the top surface of the driver 330.

In some embodiments, the light emission component 310 is located on the edge of the top of the TEC 500b, and the light reception component 320 is located beside the light emission component 310 and on the edge of the through-hole 301, such that the light reception component 320 and the light emission component 310 are arranged side by side in the width direction of the circuit board 300. The TIA 340 is located beside the light reception component 320 and the driver 330, such that the TIA 340 and the driver 330 are arranged side by side in the width direction of the circuit board 300, to fully utilize the space provided below the lens component 400 and facilitate the size control of the lens component 400.

In some embodiments, the driver 330 may be provided on the top of the TEC 500b, and the driver 330 may be located beside the light emission component 310.

FIG. 14 is a structural diagram of a circuit board provided according to some embodiments of the present disclosure. As shown in FIG. 14, an avoidance portion 3011 is provided at the side wall of the through-hole 301, such that the through-hole 301 can avoid the TEC 500b by the avoidance portion 3011, thereby facilitating the assembling of the TEC 500b. In some embodiments, the through-hole 301 is a prismatic through-hole, and the avoidance portion 3011 is provided at the corner of the through-hole 301 and formed as a rounded corner. The size of the through-hole 301 is relatively expanded at the corner of the through-hole 301, which can facilitate the assembling of the TEC 500b and effectively control the overall size of the through-hole 301 to avoid excessive overall size of the through-hole 301.

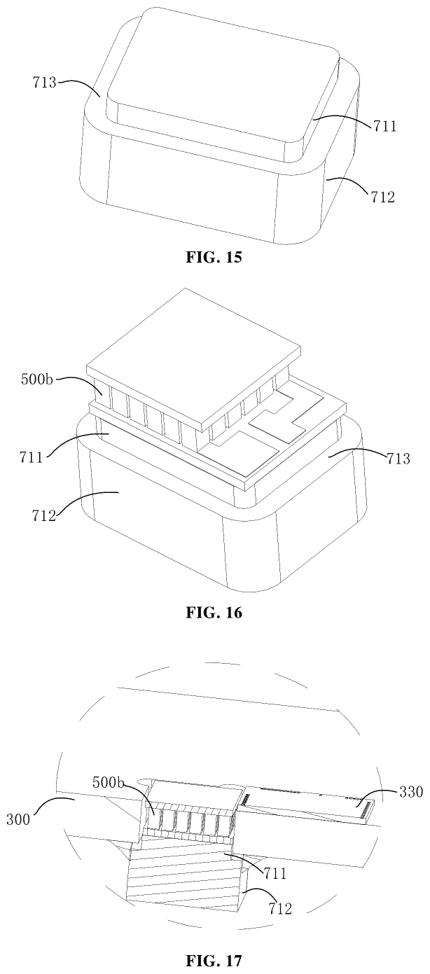

FIG. 15 is a structural diagram of another support component provided according to some embodiments of the present disclosure, and FIG. 16 is a usage state view of another support component provided according to some embodiments of the present disclosure. As shown in FIG. 15, the support component 700 includes a support portion 711 and a connection portion 712. The top of the support portion 711 supports and connects with the TEC 500b, the bottom of the support portion 711 connects to the connection portion 712, and the connection portion 712 is used to connect with the circuit board 300.

In some embodiments, a height of the support portion 711 is lower than that of the connection portion 712, which facilitates the connection of the support component 700 with the circuit board 300, and also facilitates the adaptation of the height of the TEC 500b.

In some embodiments, a cross-sectional size of the connection portion 712 is larger than that of the support portion 711, thereby forming a stepped surface 713 around the bottom of the support portion 711. The stepped surface 713 can facilitate the connection of the support component 700 to the circuit board 300 and the adjustment of the heights of the top surface of the TEC 500b and the surface of the circuit board 300. The stepped surface 713 can be connected to the bottom surface of the circuit board 300 by dispensing glue.

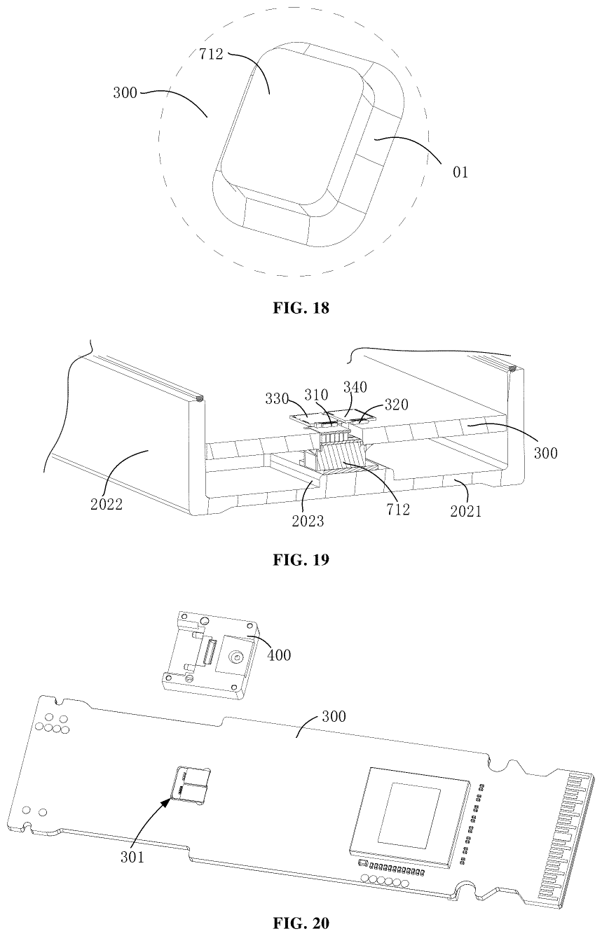

FIG. 17 is a partial assembly diagram I of another support component provided according to some embodiments of the present disclosure, and FIG. 18 is a partial assembly diagram II of another support component provided according to some embodiments of the present disclosure. As shown in FIG. 17, the top of the support portion 711 is located inside the through-hole 301, and the bottom of the support portion 711 is located outside the through-hole 301, such that the top surface of the TEC 500b is flush with or lower than the top surface of the circuit board 300, in order to ensure that the top surface of the light emission component 310 is flush with the top surface of the driver 330. As shown in FIG. 18, the thermal conductive gel 01 surrounds the sides of the connection portion 712, and the connection portion 712 is connected to the circuit board 300 by the thermal conductive gel 01.

FIG. 19 is a section view of another optical module provided according to some embodiments of the present disclosure. As shown in FIG. 19, the bottom plate 2021 is formed with a support platform 2023. The top of the support platform 2023 contacts and connects with the bottom of the connection portion 712 to facilitate the heat transfer to the lower shell part 202 through the support component 700. The top of the support platform 2023 can be connected to the connection portion 712 by thermal conductive grease or thermal conductive gel.

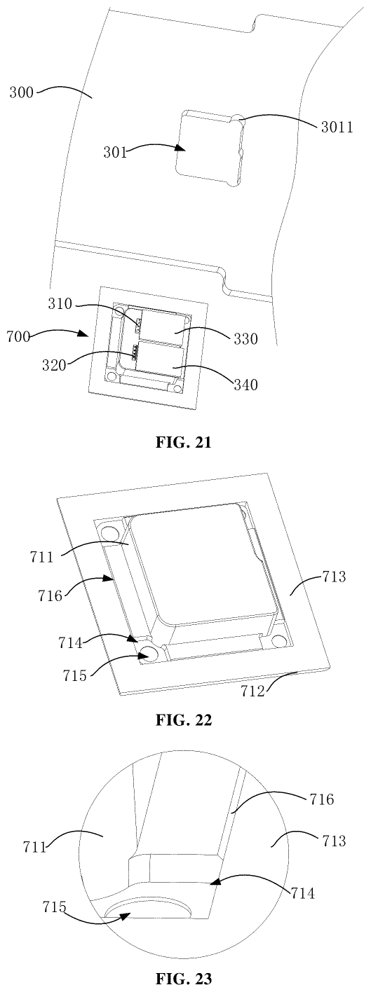

FIG. 20 is an exploded diagram I of the internal structure of another optical module provided according to some embodiments of the present disclosure, and FIG. 21 is an exploded diagram II of the internal structure of another optical module provided according to some embodiments of the present disclosure. As shown in FIGS. 20 and 21, a light emission component 310, a light reception component 320, a driver 330, a TIA 340, and a support component 700 are provided below the lens component 400. The support component 700 is connected to the circuit board 300, and the top of the support component 700 supports and connects with the light emission component 310, the light reception component 320, the driver 330, and the TIA 340. The support component 700 can use metal or the other materials having a good thermal conductivity, such as tungsten and copper. The operating temperature of the light emission component 310, the light reception component 320, the driver 330, and the TIA 340 can be effectively stabilized by the support component 700.

In some embodiments, the top of the support component 700 is located inside the through-hole 301, and a pad is provided on the edge of the through-hole 301. The drivers 330 and TIA 340 are respectively connected to the pad located on the edge of the through-hole 301 by wire bonding.

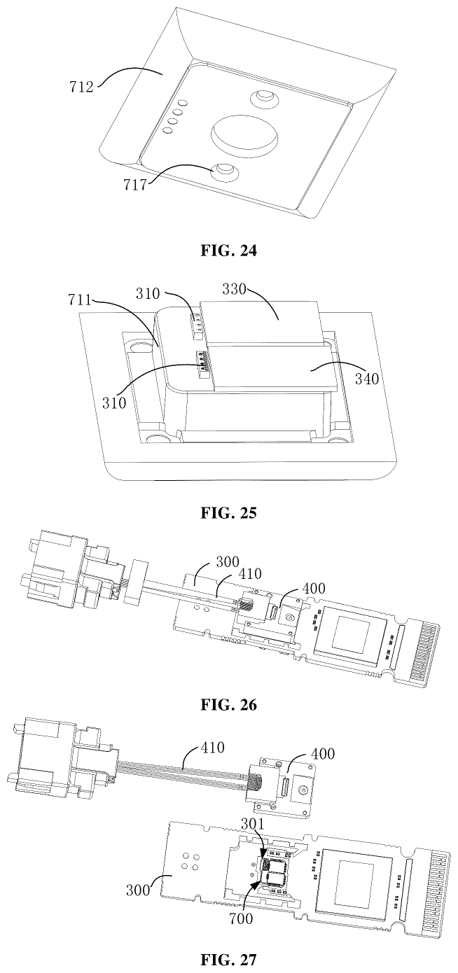

FIG. 22 is a structural diagram I of another support component provided according to some embodiments of the present disclosure, FIG. 23 is a partially enlarged view of another support component provided according to some embodiments of the present disclosure, and FIG. 24 is a structural diagram II of another support component provided according to some embodiments of the present disclosure. As shown in FIGS. 22-24, in some embodiments, the support component 700 includes a support portion 711 and a connection portion 712. The connection portion 712 is located at the bottom of the support portion 711, and the top of the connection portion 712 is formed with a stepped surface 713, which surrounds side edges of the bottom of the support portion 711 and is used to connect with the circuit board 300.

A glue-dispensing groove 714 is formed on the connection portion 712, and the glue-dispensing groove 714 is located on the edge of the bottom of the support portion 711. The top surface of the connection portion 712 is recessed to form the glue-dispensing groove 714, such that a bottom surface of the glue-dispensing groove 714 is lower than the stepped surface 713. The glue-dispensing groove 714 is used for positioning the glue during the assembly of the support component 700, facilitating glue-dispensing and glue-bearing of the support component 700.

In some embodiments, the width of the glue-dispensing groove 714 is greater than or equal to one-third of the width of the stepped surface 713, and the width of the glue-dispensing groove 714 is less than or equal to half of the width of the stepped surface 713. For example, the width of the glue-dispensing groove 714 is greater than one-third of the width of the stepped surface 713 and less than half of the width of the stepped surface 713. For example, the width of the glue-dispensing groove 714 is two-fifth of the width of the stepped surface 713. In this way, it facilitates the coordination and control of the glue-dispensing amount of the glue-dispensing groove 714 to control the assembly of support component 700 and circuit board 300.

In some embodiments, there are four glue-dispensing grooves 714 in the connection portion 712, and the four glue-dispensing grooves 714 are distributed at the bottom of four corners of the supporting portion 711. Of course, in the embodiment of the present disclosure, the stepped surface 713 may not be limited to include four glue-dispensing grooves 714 in the connection portion 712, but may include two or three glue-dispensing grooves 714, and etc.

In some embodiments, a glue-dispensing positioning groove 715 is provided on a bottom surface of the glue-dispensing groove 714, for assisting in the positioning of the glue-dispensing groove 714, such that a glue-dispensing machine can accurately dispense glue into the glue-dispensing groove 714 during dispensing glue into it. The bottom surface of glue-dispensing positioning groove 715 is lower than the bottom surface of glue dispensing groove 714. In some embodiments, a positioning protrusion can be provided in the glue-dispensing groove 714, for positioning the dispensed glue.

In some embodiments, a guiding groove 716 is provided in the connection portion 712. The guiding groove 716 is communicated with the glue-dispensing groove 714. The guiding groove 716 is used for guiding the glue, thereby effectively reducing poor assembly accuracy of the support component 700 to the circuit board 300 due to excessive glue dispensing. For example, the guiding groove 716 is provided between two adjacent glue-dispensing grooves 714, with one end of the guiding groove 716 communicated with an edge of one glue-dispensing groove 714, and the other end of the guiding groove 716 communicated with an edge of the other glue-dispensing groove 714.

In some embodiments, the glue-dispensing groove 714 has an approximately cubic structure, and the guiding groove 716 extends along a side of the glue-dispensing groove 714 that is away from the support portion 711.

In some embodiments, the bottom of the connection portion 712 is provided with an installation positioning groove 717. The installation positioning groove 717 is configured for the assembly positioning of the support component 700 to the circuit board 300 during assembly, to facilitate achieving the assembly and securement of the support component 700 and the circuit board 300.

FIG. 25 is a usage state view of another support component provided according to some embodiments of the present disclosure. As shown in FIG. 25, in some embodiments, the light emission component 310 and the light reception component 320 are arranged side by side in the width direction of the support component 700 and at a top of the support component 700, the driver 330 is arranged on a side of the light emission component 310 that is away from the optical port of the light module 200, and the TIA 340 and the driver 330 are arranged side by side in the width direction of the support component 700 and at the top of the support component 700.

The support portion 711 is located inside the through-hole 301, such that the light reception component 320 and the light emission component 310 are arranged side by side in the width direction of the circuit board 300. The TIA 340 is located beside the light reception component 320 and the driver 330, such that the TIA 340 and the driver 330 are arranged side by side in the width direction of the circuit board 300, which facilitates making full use of the space at the top of the support portion 711. It can also facilitate making full use of the space provided below the lens component 400, so as to control the size of the lens component 400.

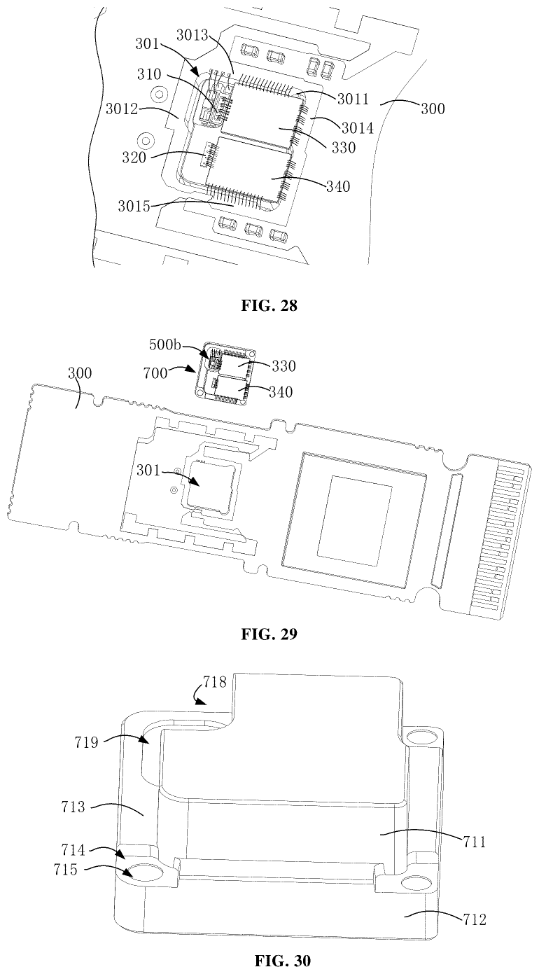

FIG. 26 is an internal structure diagram of yet another optical module provided according to some embodiments of the present disclosure, FIG. 27 is an exploded diagram I of the internal structure of yet another optical module provided according to some embodiments of the present disclosure, FIG. 28 is a partial diagram of the internal structure of yet another optical module provided according to some embodiments of the present disclosure, and FIG. 29 is an exploded diagram II of the internal structure of yet optical module provided according to some embodiments of the present disclosure. As shown in FIGS. 26 to 29, in some embodiments, a light emission component 310, a light reception component 320, a driver 330, a TIA 340, a TEC 500b, and a support component 700 are provided below the lens component 400. The support component 700 supports and connects with the light reception component 320, the driver 330, the TIA 340, and the TEC 500b. The TEC 500b supports and connects with the light emission component 310.

When the transmission rate of the laser in the light emission component 310 is not less than 200 Gb/s, it is necessary to stabilize the operating temperature of the light emission component 310 within a range of a predetermined temperature ±1° C. to ensure the performance of the laser. The support component 700 is made of materials having a good heat dissipation performance such as tungsten and copper, and the support component 700 is combined with the TEC 500b to accurately maintain the operating temperature of the light emission component 310, the light reception component 320, the driver 330, and the TIA 340 within a certain range, thereby reducing thermal crosstalk among the light emission component 310, light reception component 320, driver 330, and TIA 340. This can more effectively maintain the operating temperature of the light emission component 310, thereby ensuring the stability of the performance of the light emission component.

In some embodiments, the circuit board 300 includes a first edge 3012, a second edge 3013, a third edge 3014, and a fourth edge 3015. The first edge 3012, the second edge 3013, the third edge 3014, and the fourth edge 3015 are sequentially connected around the edge of the through-hole 301. The first edge 3012 is located on a side of the through-hole 301 that is close to the optical port of the optical module 200, the third edge 3014 is located on a side of the through-hole 301 that is away from the optical port of the optical module 200, and the second edge 3013 and the fourth edge 3015 extend along a length direction of the circuit board 300.

The light emission component 310 is connected to the driver 330 by wire bonding, the driver 330 is connected to the circuit board 300 by wire bonding, the light reception component 320 is connected to the TIA 340 by wire bonding, the TIA 340 is connected to the circuit board 300 by wire bonding, and the TEC 500b is connected to the circuit board 300 by wire bonding. For example, the driver 330 is connected to the second edge 3013 and the third edge 3014 by wire bonding, the TIA 340 is connected to the third edge 3014 and the fourth edge 3015 by wire bonding, the TEC 500b is connected to the second edge 3013 by wire bonding, and a plurality of pads are provided on the second edge 3013, third edge 3014, and fourth edge 3015, respectively.

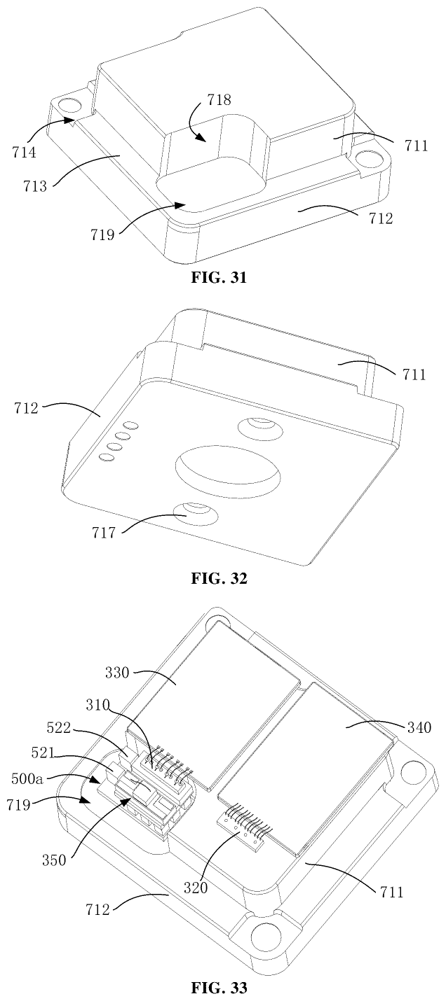

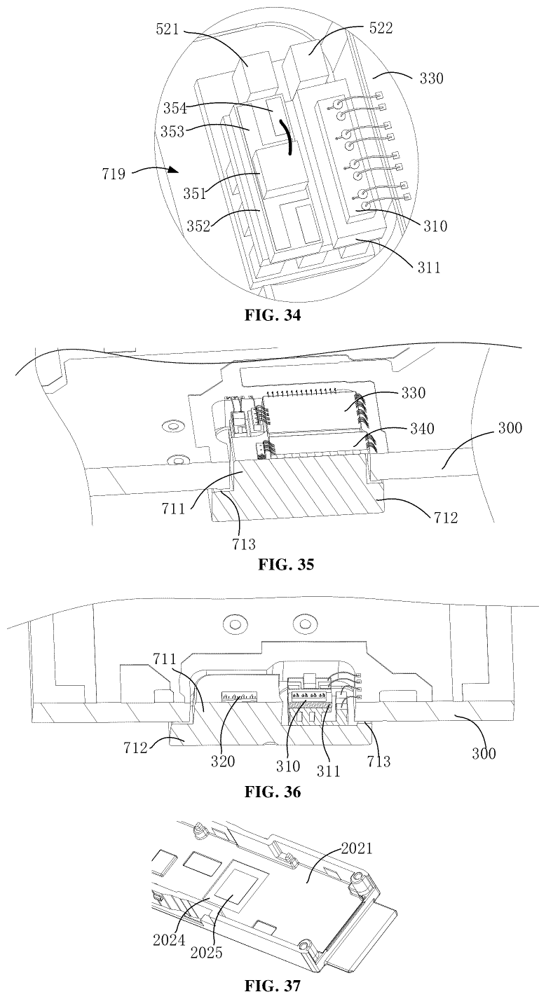

FIG. 30 is a structural diagram I of yet another support component provided according to some embodiments of the present disclosure, FIG. 31 is a structural diagram II of yet another support component provided according to some embodiments of the present disclosure, FIG. 32 is a structural diagram III of yet another support component provided according to some embodiments of the present disclosure, FIG. 33 is a usage state view of yet another support component provided according to some embodiments of the present disclosure, and FIG. 34 is a partially enlarged view of the usage state of yet another support component provided according to some embodiments of the present disclosure. In some embodiments, a thermistor component 350 may be provided below the lens component 400. The thermistor component 350 is located on the TEC 500b and beside the light emission component 310. Of course, in some embodiments, the support component 700 supports and connects with the thermistor component 350, that is, the thermistor component 350 is directly provided on the support component 700. The thermistor component 350 is used to detect the operating temperature of the light emission component 310, so as to provide a reference basis for controlling the TEC 500b.

As shown in FIGS. 30 to 32, in some embodiments, the support component 700 includes a support portion 711 and a connection portion 712. The connection portion 712 is located at the bottom of the support portion 711, and the top of the connection portion 712 and the support portion 711 forms a stepped surface 713, which surrounds side edges of the bottom of the support portion 711. The support portion 711 is formed with a cut-off corner 718 at an edge of one side thereof, which extends towards the connection portion 712.

In some embodiments, an installation groove 719 is provided at the top of the connection portion 712. The bottom surface of the installation groove 719 is lower than the stepped surface 713, and the stepped surface 713 surrounds a side of the installation groove 719. The other side of the installation groove 719 extends to the bottom of the cut-off corner 718, such that the installation groove 719 is surrounded by the support portion 711 and the stepped surface 713.

In some embodiments, an edge of the connection portion 712 is provided with a glue-dispensing groove 714. An edge of the glue-dispensing groove 714 on one side extends to the bottom of the support portion 711 and an edge thereof on the other side extends to the edge of the connection portion 712. The bottom of the glue-dispensing groove 714 is lower than the stepped surface 713. The glue-dispensing groove 714 is used to bear glue so as to facilitate dispensing glue. In some embodiments, the edge of the installation groove 719 is not provided with any glue-dispensing groove 714 to reduce the risk of glue contamination to the TEC 500b.

In some embodiments, there are three glue-dispensing grooves 714 in the connection portion 712, and the three dispensing grooves 714 are distributed at the bottom of the three corners of the supporting portion 711.

In some embodiments, a glue-dispensing positioning groove 715 is provided on the bottom surface of the glue-dispensing groove 714. The glue-dispensing positioning groove 715 is used to assist in the positioning of the glue-dispensing groove 714, such that a glue-dispensing machine can accurately dispense glue into the dispensing groove 714 during dispensing glue into it.

In some embodiments, an installation positioning groove 717 is provided at the bottom of the connection portion 712. The installation positioning groove 717 is configured for the assembly positioning of the support component 700 to the circuit board 300 during assembly, to facilitate achieving the assembly and securement of the support component 700 to the circuit board 300.

As shown in FIGS. 33 and 34, the TEC 500b is provided within the cut-off corner 718, and the bottom surface of the installation groove 719 supports and connects with the bottom of the TEC 500b. The top of the TEC 500b supports and connects with the thermistor component 350 and the light emission component 310, and the thermistor component 350 is provided beside the light emission component 310. A light reception component 320, a driver 330, and a TIA 340 are provided on the top of the support portion 711, and the driver 330 is located on the side of the light emission component 310 that is away from the thermistor component 350.

In some embodiments, one side of the driver 330 is flush with one side edge of the support portion 711, and the TIA 340 is provided on the other side of the driver 330. There is a gap between one side of the TIA 340 and the other side of the driver 330, and the gap has a width that is less than or equal to the width of the light emission component 310. The other side of the TIA 340 is flush with the other side of support portion 711, and the light reception component 320 is located beside the TIA 340. The gap is provided between the TIA 340 and the driver 330 to reduce thermal crosstalk between the TIA 340 and the driver 330.

In some embodiments, the thermistor component 350 includes a thermistor 351 and a thermistor substrate 352. A first metal layer 353 and a second metal layer 354 are provided on the top surface of the thermistor substrate 352 and form a circuit pattern on the top of the thermistor substrate 352. The top of the TEC 500b is connected to the thermistor substrate 352 The thermistor 351 is attached to the first metal layer 353 and electrically connected to the first metal layer 353, and the thermistor 351 is also connected to the second metal layer 354 by wire bonding. The first metal layer 353 and the second metal layer 354 are also connected to the circuit board 300 by wire bonding, respectively.

In some embodiments, a laser substrate 311 is also provided below the light emission component 310. The bottom of the laser substrate 311 is connected to the top of the TEC 500b, and the top of the laser substrate 311 is connected to the light emission component 310. The thermal expansion coefficient of the laser substrate 311 is similar to that of the top of the TEC 500b. In this way, the stress generated by the thermal expansion and contraction deformation of the TEC 500b can be buffered by the laser substrate 311, so that the adverse effect of the TEC 500b thermal expansion and contraction on the light emission component 310 is reduced. The laser substrate 311 can use a ceramic substrate.

In some embodiments, the width of the laser substrate 311 is greater than the width of the light emission component 310, and the length of the laser substrate 311 is greater than the length of the light emission component 310, such that the laser substrate 311 can balance the temperature across different areas of the light emission component 310.

In some embodiments, the TEC 500b includes a first electrode 521 and a second electrode 522. The first electrode 521 is located beside one end of the thermistor substrate 352 and the second electrode 522 is located beside one end of the light emission component 310. A cold surface of the TEC 500b supports and connects with the thermistor component 350 and the light emission component 310, which facilitates maintaining the operating temperature of the light emission component 310 within a relatively stable range to ensure the working performance of the light emission component 310.

FIG. 35 is an assembly section view I of yet another support component and a circuit board provided according to some embodiments of the present disclosure, and FIG. 36 is an assembly section view II of yet another support component and a circuit board provided according to some embodiments of the present disclosure. As shown in FIGS. 35-36, the support portion 711 is located inside the through-hole 301, the connection portion 712 is located below the circuit board 300, and the stepped surface 713 is connected to the bottom surface of the circuit board 300.

In some embodiments, the top surface of the support portion 711 is flush with the top surface of the circuit board 300, and the top surface of the laser substrate 311 is flush with the top surface of the circuit board 300, which facilitates the control of arc heights of the wire-bonding connections between the light emission component 310 and the driver 330, between the optical reception component 320 and the TIA 340, and between the driver 330 and TIA 340 and the circuit board 300, thereby ensuring the high-frequency signal transmission performance of the wires for transmitting high-frequency signals. Of course, in some embodiments, the top surface of the support portion 711 may be lower than the top surface of the circuit board 300, and the top surface of the laser substrate 311 may be lower than the top surface of the circuit board 300, such that the top surfaces of the light emission component 310, the light reception component 320, the driver 330, and the TIA 340 are respectively flush with the top surface of the circuit board 300.

FIG. 37 is a partial diagram of another lower shell part provided according to some embodiments of the present disclosure. As shown in FIG. 37, an accommodation groove 2024 is provided in the bottom plate 2021. The accommodation groove 2024 is configured for accommodating thermal conductive silicone grease or thermal conductive gel, etc. The thermal conductive silicone grease or the thermal conductive gel, etc. connects the bottom plate 2021 and the bottom of connection portion 712 to achieve contact and connection between the connection portion 712 and the lower shell part 202 by the thermal conductive silicone grease or the thermal conductive gel, etc., thereby facilitating heat transfer between the connection portion 712 and the lower shell portion 202.

In some embodiments, a protrusion 2025 is provided within the accommodation groove 2024. There is a gap between an edge of the protrusion 2025 and an edge of the accommodation groove 2024 for containing spilled thermal conductive silicone grease or thermal conductive gel, etc., such that the protrusion 2025 supports the bottom of the connection portion 712. The combination of the accommodation groove 2024 and the protrusion 2025 can improve the heat transfer efficiency between the connection portion 712 and the lower shell part 202, thereby fully ensuring the heat dissipation of the support component 700.

In some embodiments, the optical module 200 is not limited to include one lens component 400, but may include two or more lens components. In the case that there are two lens components 400 in the optical module 200, the arrangement of the devices below the two lens components 400 can refer to that of the devices below one lens component 400 of the optical module 200 mentioned above.

Finally, it should be noted that the above embodiments are used to illustrate the technical solution of the present disclosure rather than provide a limit to it. Although detailed explanations of the present disclosure have been provided with reference to the aforementioned embodiments, those skilled in the art should understand that they can still modify the technical solutions recorded in the aforementioned embodiments, or equivalently replace some of the technical features therein. These modifications or replacements do not make the essence of the corresponding technical solutions deviate from the spirit and scope of the technical solutions disclosed in the present disclosure.

What is claimed is:

1. An optical module comprising:
a circuit board, which is provided with a through-hole;
a light emission component for generating an optical signal;
a driver, which is electrically connected to the circuit board, located beside the light emission component, and electrically connected to the light emission component;
a lens component, which is connected to the circuit board at its bottom and is covered over the light emission component, configured to change a transmission direction of the optical signal generated by the light emission component;
a support component, which has a top located inside the through-hole and is connected to the circuit board, with a thermal conductivity coefficient of the support component being greater than or equal to that of the circuit board; and
a temperature regulating mechanism, which is located below the lens component and its bottom is connected to the support component; wherein the temperature regulating mechanism is located below or beside the light emission component, configured to regulate an operating temperature of the light emission component.

2. The optical module according to claim 1, wherein the support component comprises a support portion located inside the through-hole and a connection portion connected to the circuit board;
wherein a cut-off corner is formed at one side of the support portion, and a top of the support portion supports and connects with the driver;
wherein the temperature regulating mechanism comprises a TEC provided within the cut-off corner, and a top of the TEC supports and connects with the light emission component; wherein the TEC is electrically connected to the circuit board and is configured to regulate the operating temperature of the light emission component.

3. The optical module according to claim 2, further comprising a light reception component and a TIA, wherein the light reception component and the TIA are located below the lens component, and the light reception component and the TIA are provided at the top of the support component;
wherein the light reception component and the driver are respectively located beside the cut-off corner, and the TIA is located beside the driver and the light reception component; and
wherein the optical emission component is connected to the driver by wire bonding, and the driver is connected to the circuit board by wire bonding; and the light reception component is connected to the TIA by wire bonding, and the TIA is connected to the circuit board by wire bonding.

4. The optical module according to claim 2, wherein a top of the connection portion is formed with a stepped surface and a glue-dispensing groove, and the stepped surface surrounds a side edge of a bottom of the support portion and is connected to the circuit board; and
wherein the glue-dispensing groove is located at an edge of the bottom of the support portion, and a bottom surface of the glue-dispensing groove is lower than the stepped surface; wherein the glue-dispensing groove is used for providing a glue-dispensing positioning groove therein, with a bottom surface of the glue-dispensing positioning groove being lower than a bottom surface of the glue-dispensing groove.

5. The optical module according to claim 2, wherein a top of the TEC is further provided with a thermistor component, which is located on a side of the light emission component that is away from the driver;
wherein the thermistor component comprises a thermistor and a thermistor substrate, a first metal layer and a second metal layer are provided on a top surface of the thermistor substrate, and the thermistor is mounted on the first metal layer and connected to the second metal layer by wire bonding; and
wherein the first metal layer and the second metal layer are respectively connected to the circuit board by wire bonding.

6. The optical module according to claim 5, wherein a top of the TEC is further provided with a laser substrate, with a bottom of the laser substrate being connected to the TEC, and a top of the laser substrate supporting and connecting with the light emission component;
wherein a width of the laser substrate is greater than that of the light emission component, and a length of the laser substrate is greater than that of the light emission component; and there is a gap between the laser substrate and the thermistor substrate.

7. The optical module according to claim 1, further comprising a lower shell part, wherein a bottom plate of the lower shell part is provided with an accommodation groove, a protrusion is provided within the accommodation groove, and the protrusion supports and connects with the bottom of the support component; and wherein conductive grease or thermal conductive gel are filled in a gap formed between the accommodation groove and the protrusion.

8. The optical module according to claim 1, wherein the temperature regulating mechanism comprises a TEC provided at the top of the support component, and a top of the TEC supports and connects with the light emission component.

9. The optical module according to claim 8, wherein the driver is provided on the circuit board and is located beside the through-hole, and the driver is connected to the light emission component by wire bonding.

10. The optical module according to claim 7, wherein the support component comprises a support portion located inside the through-hole and a connection portion connected to the circuit board by wire bonding; and
wherein the TEC is provided at the top of the support portion, and a height of the support portion is lower than that of the connection portion; an avoidance portion is provided on a side wall of the through-hole, and is located at a corner of the through-hole.

11. The optical module according to claim 8, wherein the top of the TEC supports and connects with the driver, and the driver is connected to the circuit board by wire bonding; and
wherein the top surface of the TEC is lower than the top surface of the circuit board, or the top surface of the TEC is flush with the top surface of the circuit board.

12. The optical module according to claim 8, further comprising a light reception component and a TIA, wherein the light reception component and the TIA are located below the lens component;
wherein the light reception component and the TIA are respectively located at the top of the support component; or
wherein the light reception component and the TIA are provided on the circuit board and beside the through-hole, the light reception component and the light emission component are arranged side by side in a width direction of the circuit board, the TIA is located beside the driver, and the TIA and the driver are arranged side by side in the width direction of the circuit board.

13. The optical module according to claim 1, wherein the temperature regulating mechanism comprises a heating element, the heating element is provided at the top of the support component, and the heating element is provided beside the light emission component or below the light emission component.

14. The optical module according to claim 13, wherein the heating element comprises a substrate, and a heating layer, a first pad, and a second pad are provided on the substrate, with one end of the heating layer being connected to the first pad, the other end of the heating layer being connected to the second pad, and the heating layer extending from one end of the light emission component to the other end of the light emission component; and the first pad and the second pad are electrically connected to the circuit board.

15. The optical module according to claim 13, wherein the support component is connected to the circuit board by adhesive, and the bottom of the support component does not contact the shell of the optical module.

16. The optical module according to claim 14, wherein the driver is provided beside the through-hole; and
wherein the heating layer is provided on an edge of the top of the substrate, located on a side edge of the substrate that is away from the driver; and a bottom of the light emission component is connected to the substrate.

17. The optical module according to claim 3, wherein the circuit board comprises a first edge, a second edge, a third edge, and a fourth edge sequentially surround side edges of the through-hole; wherein the first edge is located on a side of the through-hole that is near an optical port of the optical module, and the third edge is located on a side of the through-hole that is away from the optical port of the optical module; and
wherein the second edge, the third edge, and the fourth edge are respectively provided with pads, and the driver is connected to the second edge and the third edge by wire bonding, and the TIA is connected to the third edge and the fourth edge by wire bonding.

18. An optical module comprising:
a circuit board, which is provided with a through-hole;
a lens component, a bottom of which is connected to the circuit board, wherein the lens component is configured for changing a transmission direction of an optical signal;
an optical chip, which is provided below the lens component, and comprises at least one of a light emission component and a light reception component; and
a support component, which connects with the circuit board, and has a top located inside the through-hole; the support component supports and connects with the optical chip, and a thermal conductivity coefficient of the support component is greater than that of the circuit board.

19. The optical module according to claim 18, further comprising a temperature regulating mechanism, wherein the temperature regulating mechanism is located below the lens component and its bottom is connected to the support component, and the temperature regulating mechanism is located below or beside the optical chip.

20. An optical module comprising:
a circuit board, which is provided with a through-hole;
a lens component, a bottom of which is connected to the circuit board, wherein the lens component is configured for changing a transmission direction of an optical signal;
an optical chip, which is located below the lens component, and comprises at least one of a light emission component and a light reception component;
a matching chip, which is located below the lens component and beside the optical chip, correspondingly connected to the optical chip by wire bonding; and the matching chip comprises at least one of a driver and a TIA; and
a support component, which connects with the circuit board, and has a top located inside the through-hole; the support component supports and connects with the optical chip and the matching chip, and a thermal conductivity coefficient of the support component is greater than that of the circuit board.
